(19) United States
(12) Patent Application Publication
(10) Pub. No.: US 2017/0002242 A1
(43) Pub. Date: Jan. 5, 2017

(54) ADHESIVE COMPOSITION USING POLYAMIDE-IMIDE RESIN

(71) Applicants: TOYOBO CO., LTD., Osaka-shi (JP); NIPPON MEKTRON, LTD., Tokyo (JP)

(72) Inventors: Takehisa YANE, Shiga (JP); Hideyuki KOYANAGI, Shiga (JP); Masami HAMANO, Shiga (JP); Hisae OBA, Tokyo (JP); Kouji OKANO, Tokyo (JP); Satoshi EBIHARA, Tokyo (JP)

(73) Assignees: TOYOBO CO., LTD., Osaka-shi (JP); NIPPON MEKTRON, LTD., Tokyo (JP)

(21) Appl. No.: 15/104,273

(22) PCT Filed: Jan. 5, 2015
(86) PCT No.: PCT/JP2015/050017

§ 371 Date: Jun. 14, 2016

(30) Foreign Application Priority Data
May 28, 2014 (JP) 2014-109776

(51) Int. Cl. C09J 179/08; C09J 7/02; H05K 1/03; C09J 11/06

(52) U.S. Cl. CPC C09J 179/08; C09J 11/06; C09J 7/0292; H05K 1/0373; H05K 1/0393; C08K 5/5313

(57) ABSTRACT

The present invention provides an adhesive composition for a flexible printed wiring board containing (A) an epoxy resin; (B) no phosphorus-containing epoxy resin; and (C) a polyamide-imide resin.

### TECHNICAL FIELD OF THE INVENTION

The present invention relates to an adhesive composition using a polyamide-imide resin and, more particularly, it relates to an adhesive composition which is excellent in insulating property, flexibility, flame retarding property and fluidity and is suitable for a coverlay film, an adhesive film, a three-layered copper-lined layered plate, etc.

### BACKGROUND ART

A polyamide-imide resin is polymerized from an aromatic monomer, exhibits characteristics such as high resistance to heat, chemicals and abrasion, and shows solubility in solvents of a high-boiling amide type such as N-methyl-2-pyrrolidone. Accordingly, it has been used for molding materials, heat-resistant insulating paints, etc. However, a polyamide-imide resin of an aromatic type is usually highly elastic, hard and brittle. Also, it has poor solubility in low-boiling solvents. Accordingly, it is difficult to use the polyamide-imide resin of an aromatic type for applications such as an adhesive which requires flexibility and high drying property of solvent.

A flexible printed wiring board has been widely used in electronic instrument parts for which flexibility and space conservation are demanded such as a device substrate of display for liquid crystal display, plasma display, etc., a substrate junction cable and a substrate for operating switches for mobile phones, digital cameras, portable game machines, etc. and expansion to further applications has been expected.

An adhesive used for a flexible printed wiring board is used in the sites constituting the flexible printed wiring board such as a coverlay film, an adhesive film and a three-layered copper-lined layered plate. For the adhesive used in such a use, insulating property, flexibility, flame retarding property and fluidity are demanded in addition to adhesiveness and heat resistance.

With regard to the adhesives used for a flexible printed wiring board, an epoxy resin or an acrylic resin has been used up to now but the adhesive as such does not have sufficient heat resistance in order to cope with the recent tendencies for high density of the wiring and for lead-free solder. As an adhesive having heat resistance in place of the above ones, a polyimide resin has been investigated. The conventional polyimide resin has advantages that it is highly elastic, hard and brittle whereby expression of adhesive property is difficult and that it is soluble only in high-boiling solvent. In order to solve such disadvantages of the conventional polyimide resin, investigation of copolymerization of the polyimide resin with a long-chain monomer or oligomer has been carried out. For example, a polysiloxane-modified polyimide resin is proposed in Patent Documents 1 and 2 as a means for imparting the flexibility.

However, in the polysiloxane-modified polyimide resin, it is necessary to use a very expensive starting material having a siloxane bond for imparting the flexibility whereby it is inferior in view of economy. In addition, as a result of an increase in a copolymerizing amount of polysiloxane, there is a risk of a decrease in adhesiveness of the resin. As to the solvent, even a soluble polysiloxane-modified polyimide resin uses a high-boiling N-methyl-2-pyrrolidone. As a result, drying thereof is difficult.

In Patent Documents 3 and 4, there is proposed a method wherein a polyimide resin is copolymerized with acrylonitrile butadiene having reactive functional groups in both terminals of a molecule. Although it is possible to impart flexibility and to enhance adhesive property to some extent by such a method, it is necessary to increase a copolymerizing amount of acrylonitrile butadiene in order to express sufficient adhesive property by this method. As a result, there is a risk that reliability for the insulation lowers.

In the application as a flexible printed wiring board, there has been a demand for a resin which is excellent in all terms of adhesive property, heat resistance, flexibility, insulating property, adhesive property and solubility in low-boiling solvents. As mentioned above however, there has been achieved no resin in the prior art being suitable as a heat-resisting adhesive which satisfies all of heat resistance, flexibility, adhesive property, insulating property and solubility in solvents and can be used for the application as such a flexible printed wiring board.

### PRIOR ART DOCUMENTS

### Patent Documents

Patent Document 1: Japanese Patent Application Laid-Open (JP-A) No. 2004-250577

Patent Document 2: Japanese Patent Application Laid-Open (JP-A) No. 2005-179513

Patent Document 3: Japanese Patent Application Laid-Open (JP-A) No. 2003-289594

Patent Document 4: Japanese Patent No. 3931387

### DISCLOSURE OF THE INVENTION

### Problem that the Invention is to Solve

The present invention has been done for solving the above problems in the prior art and its object is to provide an adhesive composition using a polyamide-imide resin suitable for the use such as a flexible printed wiring board.

### Means for Solving the Problem

The present inventors have carried out eager investigations for achieving the above object and, as a result, they have resulted in the present invention by means of combining a polyamide-imide resin with an epoxy resin, each of which has a specific composition.

Thus, the present invention consists of the constitutions of the following (1) to (11).

(1) An adhesive composition wherein a polyamide-imide resin and an epoxy resin are compounded, characterized in that said adhesive composition has characteristics of the following (A) to (C):

(A) 15 parts by mass to 40 parts by mass of the epoxy resin is compounded to 85 parts by mass to 60 parts by mass of the polyamide-imide resin;

(B) No phosphorus-containing epoxy resin is used as the epoxy resin or, even if used, a compounding amount of the phosphorus-containing epoxy resin to 100 parts by mass of the polyamide-imide resin is less than 1 part by mass; and

(C) The polyamide-imide resin is a polyamide-imide resin comprising a constituent unit derived from acid ingredients of the following (a) to (c) and a constituent unit derived from a diisocyanate ingredient having an aromatic ring or derived from a diamine ingredient having an aromatic ring and,

when the constituent units derived from total acid ingredients in the polyamide-imide resin are taken as 100 mol %, a rate of each constituent unit derived from each acid ingredient is 1 to 6 mol % for (a), 10 to 80 mol % for (b) and 10 to 89 mol % for (c):

(a) acrylonitrile-butadiene rubber which has carboxyl groups in both terminals, has weight-average molecular weight of 500 to 5,000, and has a rate of an acrylonitrile moiety of 10 to 50% by mass;

(b) aliphatic dicarboxylic acid which has a carbon number of 4 to 12; and

(c) anhydride of polycarboxylic acid which has an aromatic ring.

(2) The adhesive composition according to (1), wherein a phosphorus-type flame retardant is further compounded therewith and a content of phosphorus in a nonvolatile ingredient in the adhesive composition is 1.0 to 5.0% by mass.

(3) The adhesive composition according to (2), wherein a phosphorus-type flame retardant having no functional group which is reactive with epoxy and a phosphorus-type flame retardant having two or more functional groups which are reactive with epoxy are jointly used as the phosphorus-type flame retardant.

(4) The adhesive composition according to any of (1) to (3), wherein a total amount of chlorine of the epoxy resin is 500 ppm or less in the nonvolatile ingredient of the adhesive composition.

(5) The adhesive composition according to any of (1) to (4), wherein a resin having glass transition temperature of 200° C. or higher is further compounded therewith.

(6) A coverlay film which is characterized in using an adhesive layer made from the adhesive composition mentioned in any of (1) to (5).

(7) The coverlay film according to (6), wherein an amount of residual solvent in the coverlay film in a state of B stage is less than 1.5% by mass.

(8) An adhesive film which is characterized in using an adhesive layer made from the adhesive composition mentioned in any of (1) to (5).

(9) The adhesive film according to (8), wherein an amount of residual solvent in the adhesive film in a state of B stage is less than 1.5% by mass.

(10) A three-layered copper-lined layered plate which is characterized in using an adhesive layer made from the adhesive composition mentioned in any of (1) to (5).

(11) A flexible printed wiring board which is characterized in using the adhesive composition mentioned in any of (1) to (5), the coverlay film mentioned in (6) or (7), the adhesive film mentioned in (8) or (9), or the three-layered copper-lined layered plate mentioned in (10).

### Advantages of the Invention

Acrylonitrile butadiene rubber and aliphatic dicarboxylic acid are introduced in specific rates into the polyamide-imide resin used in the adhesive composition of the present invention. Accordingly, it is possible to express flexibility and insulating property without deteriorating the heat resistance which has been exhibited in the conventional polyamide-imide resin. In addition, as a result of combining with the specific epoxy resin, it is possible to provide an adhesive composition which is very suitable as a component part using an adhesive, said component part being used for a flexible printed wiring board.

The polyamide-imide resin used in the adhesive composition of the present invention is a polyamide-imide resin comprising a constituent unit derived from acid ingredients of the following (a) to (c) and a constituent unit derived from a diisocyanate ingredient having an aromatic ring or derived from a diamine ingredient having an aromatic ring and,

when the constituent units derived from total acid ingredients in the polyamide-imide resin are taken as 100 mol %, a rate of each constituent unit derived from each acid ingredient is 1 to 6 mol % for (a), 10 to 80 mol % for (b) and 10 to 89 mol % for (c):

(a) acrylonitrile-butadiene rubber which has carboxyl groups in both terminals, has weight-average molecular weight of 500 to 5,000, and has a rate of an acrylonitrile moiety of 10 to 50% by mass;

(b) aliphatic dicarboxylic acid which has a carbon number of 4 to 12; and

(c) anhydride of polycarboxylic acid which has an aromatic ring.

The (a) acrylonitrile-butadiene rubber which has carboxyl groups in both terminals, has weight-average molecular weight of 500 to 5,000, and has a rate of an acrylonitrile moiety of 10 to 50% by mass in the present invention is used for imparting flexibility and adhesive property to the polyamide-imide resin and is introduced in an amount of 1 to 6 mol % to the total acid ingredient of the polyamide-imide or, in other words, is copolymerized therewith. Since the ingredient (a) has carboxyl groups, it can be copolymerized in the polymerization of the polyamide-imide resin which will be mentioned later. With regard to its molecular weight, it is not possible to impart flexibility and adhesive property when it is too low while, when it is too high, the copolymerization is difficult. Further, when the acrylonitrile moiety is too small, compatibility lowers and the copolymerization is difficult while, when it is too much, insulating property lowers. Accordingly, the rate of acrylonitrile in terms of the sole ingredient (a) is preferred to be 10 to 50% by weight and the copolymerizing amount with the polyamide-imide resin is preferred to be 1 to 6 mol %, more preferred to be 1 to 3 mol %, and most preferred to be less than 3 mol %. Incidentally, in the present invention, the introducing rate of each material will now be illustrated in such a manner that, in the polymerization of the polyamide-imide resin, each of the total acid ingredient and the total isocyanate ingredient is taken as 100 mol %.

As to commercially available acrylonitrile butadiene rubber having carboxyl groups in both terminals satisfying the above conditions for the ingredient (a), there may be exemplified the CTBN series of Hypro™ of Emerald Performance Materials, etc. However, in order to impart flexibility and adhesive property by means of copolymerization of the ingredient (a) only, it is necessary to make its introducing amount abundant. In such a case, insulating property lowers, and thus it is difficult to achieve a balance among the characteristics. This is the reason why the ingredient (b) which will be mentioned later is necessary.

The (b) aliphatic dicarboxylic acid which has a carbon number of 4 to 12 in the present invention is used for imparting adhesive property and solubility in solvent to the polyamide-imide resin. The ingredient (b) is copolymerized in an amount of 10 to 80 mol % to the total acid ingredients of the polyamide-imide. When the copolymerizing rate of the ingredient (b) is too small, no sufficient effect can be achieved while, when it is too much, the rate of aromatic ingredient in the polyamide-imide resin lowers whereby heat resistance lowers. Accordingly, the introducing amount of the ingredient (b) is preferred to be 10 to 80 mol %, and more preferred to be 30 to 55 mol %. Here, the carbon number of the ingredient (b) is a number including the carbons of carboxylic acid moiety. Accordingly, it shall be 10 in the case of sebacic acid for example. When the carbon number is more than 12, a part having low polarity in the polyamide-imide resin becomes too much whereby there is resulted a problem that solubility of the resin and adhesive property become low. In addition, when the ingredient (b) is used solely, it is difficult to impart flexibility because its molecular chain is short. In order to satisfy all of heat resistance, flexibility, adhesive property and solubility in low-boiling solvents in the resulting polyamide-imide resin, it is necessary that both ingredients (a) and (b) are copolymerized in a specific ratio.

As to the ingredient (b), there may be exemplified aliphatic dicarboxylic acid in a straight chain and aliphatic dicarboxylic acid having a branched structure. Examples thereof in a straight chain structure are succinic acid, glutaric acid, adipic acid, heptanoic diacid, octanoic diacid, azelaic acid, sebacic acid, undecanoic diacid and dodecanoic diacid. Examples thereof having a branched structure are those where the above dicarboxylic acid is substituted with hydrocarbon such as 2-methylsuccinic acid. Each of them may be used solely or two or more thereof may be used jointly.

The (c) anhydride of polycarboxylic acid which has an aromatic ring in the present invention is a material which has been conventionally used for a polyamide-imide resin. Since it has the aromatic ring, it imparts heat resistance to the resulting resin. The ingredient (c) is copolymerized in an amount of 10 to 89 mol %, and preferably 30 to 70 mol %, with the total acid ingredients of polyamide-imide. As to the ingredient (c), there may be exemplified trimellitic acid anhydride, pyromellitic acid dianhydride, alkylene glycol bisanhydrotrimellitate (such as ethylene glycol bisanhydrotrimellitate, propylene glycol bisanhydrotrimellitate, 1,4-butanediol bisanhydrotrimellitate, hexamethylene glycol bisanhydrotrimellitate, polyethylene glycol bisanhydrotrimellitate and polypropylene glycol bisanhydrotrimellitate), trimellitic acid anhydride, 3,3′,4,4′-benzophenone-tetracarboxylic acid dianhydride, 3,3′,4,4′-biphenyl-tetracarboxylic acid dianhydride, 1,2,5,6-naphthalene-tetracarboxylic acid dianhydride, 1,4,5,8-naphthalene-tetracarboxylic acid dianhydride, 2,3,5,6-pyridine-tetracarboxylic acid dianhydride, 3,4,9,10-perylene-tetracarboxylic acid dianhydride, 3,3′,4,4′-diphenylsulfone-tetracarboxylic acid dianhydride, 4,4′-oxydiphthalic acid dianhydride, 1,1,1,3,3,3-hexafluoro-2,2-bis(2,3- or 3,4-dicarboxyphenyl)propane dianhydride, 2,2-bis(2,3- or 3,4-dicarboxyphenyl)propane dianhydride, 2,2-bis[4-(2,3- or 3,4-dicarboxyphenoxy)phenyl]propane dianhydride, 1,1,1,3,3,3-hexafluoro-2,2-bis[4-(2,3- or 3,4-dicarboxyphenoxy)phenyl]propane dianhydride and 1,3-bis(3,4-dicarboxylphenyl)-1,1,3,3-tetramethyldisiloxane dianhydride. Each of them may be used solely or two or more thereof may be used jointly.

Besides the already-mentioned ingredients (a) to (e), it is also possible to use aliphatic or alicyclic acid anhydrides and aromatic or alicyclic dicarboxylic acids as other acid ingredients within such an extent that they do not deteriorate the effect of the present invention. For example, there may be listed a compound wherein any of the above-mentioned ingredients is hydrogenated, meso-butane-1,2,3,4-tetra-carboxylic acid dianhydride, pentane-1,2,4,5-tetracarboxylic acid dianhydride, cyclobutane-tetracarboxylic acid dianhydride, cyclopentane-tetracarboxylic acid dianhydride, cyclohex-1-ene-2,3,5,6-tetracarboxylic acid dianhydride, 3-ethylcyclohex-1-ene-3-(1,2),5,6-tetracarboxylic acid dianhydride, 1-methyl-3-ethylcyclohexane-3-(1,2),5,6-tetracarboxylic acid dianhydride, 1-methyl-3-ethylcyclohex-1-ene-3-(1,2),5,6-tetracarboxylic acid dianhydride, 1-ethylcyclohexane-1-(1,2),3,4-tetracarboxylic acid dianhydride, 1-propylcyclohexane-1-(2,3),3,4-tetracarboxylic acid dianhydride, 1,3-dipropylcyclohexane-1-(2,3),3-(2,3)-tetracarboxylic acid dianhydride, dicyclohexyl-3,4,3′,4′-tetracarboxylic acid dianhydride, bicyclo[2.2.1]heptane-2,3,5,6-tetracarboxylic acid dianhydride, 1-propylcyclohexane-1-(2,3),3,4-tetracarboxylic acid dianhydride, 1,3-dipropylcyclohexane-1-(2,3), 3-(2,3)-tetracarboxylic acid dianhydride, dicyclohexyl-3,4,3′,4′-tetracarboxylic acid dianhydride, bicyclo[2.2.1]heptane-2,3,5,6-tetracarboxylic acid dianhydride, bicyclo[2.2.2]octane-2,3,5,6-tetracarboxylic acid dianhydride, bicyclo[2.2.2]oct-7-ene-2,3,5,6-tetracarboxylic acid dianhydride, cyclohexane dicarboxylic acid, terephthalic acid, isophthalic acid, orthophthalic acid, naphthalene dicarboxylic acid and oxydibenzoic acid. Each of them may be used solely or two or more thereof may be used jointly. In view of the heat resistance of the resulting polyamide-imide resin and of the flame retarding property of the adhesive composition using the same, a rate of the above ingredient in the total acid ingredients is preferred to be 20 mol % or less.

Examples of the diisocyanate having an aromatic ring used in the present invention are diphenylmethane 2,4′-diisocyanate, diphenylmethane 4,4′-diisocyanate, 3,2′- or 3,3′- or 4,2′- or 4,3′- or 5,2′- or 5,3′- or 6,2′- or 6,3′-dimethyldiphenyl-methane 2,4′-diisocyanate, 3,2′- or 3,3′- or 4,2′- or 4,3′- or 5,2′- or 5,3′- or 6,2′ or 6,3′-diethyldiphenylmethane 2,4′-diisocyanate, 3,2′- or 3,3′- or 4,2′- or 4,3′- or 5,2′- or 5,3′- or 6,2′- or 6,3′-dimethoxydiphenylmethane 2,4′-diisocyanate, diphenylmethane 4,4′-diisocyanate, diphenylmethane 3,3′-diisocyanate, diphenylmethane 3,4′-diisocyanate, diphenyl ether 4,4′-diisocyanate, benzophenone 4,4′-diisocyanate, diphenylsulfone 4,4′-diisocyanate, tolylene 2,4-diisocyanate, tolylene 2,6-diisocyanate, m-xylylene diisocyanate, p-xylylene diisocyanate, naphthalene 2,6-diisocyanate, 4,4′-[2,2-bis(4-phenoxyphenyl)propane] diisocyanate, 3,3′- or 2,2′-dimethylbiphenyl 4,4′-diisocyanate, 3,3′- or 2,2′-diethylbiphenyl 4,4′-diisocyanate, 3,3′-dimethoxybiphenyl 4,4′-diisocyanate and 3,3′-diethoxybiphenyl 4,4′-diisocyanate. Examples of the diamine ingredient having an aromatic ring used in the present invention are diamines corresponding to the above diisocyanates. Each of them may be used solely or two or more thereof may be used jointly.

Aliphatic or alicyclic structure may be used as the diisocyanate ingredient or the diamine ingredient within such an extent that the effect of the present invention is not deteriorated thereby. For example, there may be used diisocyanate or diamine in which any of the above-mentioned ingredients is hydrogenated. In addition, there may be also exemplified isophorone diisocyanate, 1,4-cyclohexane diisocyanate, 1,3-cyclohexane diisocyanate, 4,4′-dicyclohexylmethane diisocyanate, ethylene diisocyanate, propylene diisocyanate and hexamethylene diisocyanate as well as diamines corresponding thereto. Each of them may be used solely or two or more thereof may be used jointly. In view of heat resistance of the resulting polyamide-imide resin and of flame retarding property of the adhesive composition using the same, a rate of the above ingredient in the isocyanate ingredient or in the amine ingredient is preferred to be 20 mol or less.

For a purpose of enhancing heat resistance of the resulting adhesive composition by increasing reactive points with an epoxy resin, the polyamide-imide resin of the present invention may be copolymerized with a compound having three or more functional groups. Examples thereof include a polyfunctional carboxylic acid such as trimesic acid, a dicarboxylic acid having hydroxyl group such as 5-hydroxyisophthalic acid, a dicarboxylic acid having amino group such as 5-aminoisophthalic acid, a compound having three or more hydroxyl groups such as glycerol and polyglycerol and a compound having three or more amino groups such as tris(2-aminoethyl)amine. Among them, the dicarboxylic acid having hydroxyl group such as 5-hydroxyisophthalic acid and the compound having three or more amino groups such as tris(2-aminoethyl)amine are preferred in view of reactivity and solubility and the amount thereof to the acid ingredient or to the amine ingredient is preferred to be 20 mol % or less. When the amount is more than 20 mol %, there may be a risk that, upon preparing a polyamide, gelling happens or insoluble substance is produced.

In the polyamide-imide resin of the present invention, there may be used polyester, polyether, polycarbonate, dimer acid, polysiloxane, etc. as the ingredients for imparting flexibility and adhesive property other than the acrylonitrile-butadiene rubber and the aliphatic dicarboxylic acid having a carbon number of 4 to 12 within such an extent that the effect of the present invention is not deteriorated thereby. When the copolymerizing amount with the polyamide-imide resin at that time is too much, there is a risk that the effect of the present invention such as heat resistance, solubility and adhesive property may be deteriorated. Accordingly, a rate of the above ingredients to the total acid ingredients or to the isocyanate ingredient is preferred to be 10 mol % or less.

The polyamide-imide resin of the present invention can be produced by a known method such as a method wherein the polyamide-imide resin is produced from an acid ingredient and an isocyanate ingredient (isocyanate method), a method wherein an acid ingredient and an amine ingredient are made to react and then the resulting amic acid is subjected to ring closure (direct method) or a method wherein a compound having acid anhydride and acid chloride is made to react with diamine. In an industrial scale, the isocyanate method is advantageous.

With regard to a method for producing the polyamide-imide resin, although the isocyanate method is mentioned hereinafter as a representative one, it is also possible to produce the polyamide-imide resin similarly by the above acid chloride method or direct method using the corresponding amine and acid/acid chloride.

The polymerization reaction for the polyamide-imide resin according to the present invention may be carried out in such a manner that the acid ingredient and the isocyanate ingredient are stirred while heating at 60 to 200° C. in a solvent as being publicly known already. At that time, the molar ratio of (the acid ingredient)/(the isocyanate ingredient) is preferred to be within a range of from 90/100 to 100/90. Incidentally, it is general that the amounts of the acid ingredient and the isocyanate ingredient in the polyamide-imide resin are the same as the ratios of the ingredients upon polymerization. In order to promote the reaction, there may be used a catalyst such as an alkali metal compound (such as sodium fluoride, potassium fluoride or sodium methoxide), an amine (such as triethylenediamine, triethylamine, 1,8-diazabicyclo[5.4.0]-7-undecene or 1,5-diazabicyclo-[4.3.0]-5-nonene) and dibutyl tin laurate. When an amount of the catalyst as such is too small, no catalytic effect is achieved while, when it is too much, there is a possibility of causing the side reaction. Accordingly, when the ingredient having more molar numbers between the molar numbers of the acid ingredient and of the isocyanate ingredient is taken as 100 mol %, the catalyst is preferred to be used in 0.01 to 5 mol %, and more preferred to be used in 0.1 to 3 mol %, of the catalyst.

As to a solvent which can be used for the polymerization of the polyamide-imide resin of the present invention, there may be exemplified N-methyl-2-pyrrolidone, γ-butyrolactone, dimethylimidazolidinone, dimethylsulfoxide, dimethylformamide, dimethylacetamide, cyclohexanone and cyclopentanone. Among them, dimethylacetamide is preferred due to its low boiling point and good polymerization efficiency. After the polymerization, dilution with the solvent used for the polymerization or with other low-boiling solvent is carried out whereby concentration of the nonvolatile substance or viscosity of the solution can be adjusted.

As to a low-boiling solvent, there may be exemplified an aromatic solvent such as toluene or xylene, an aliphatic solvent such as hexane, heptane or octane, an alcoholic solvent such as methanol, ethanol, propanol, butanol or isopropanol, a ketonic solvent such as acetone, methyl ethyl ketone, methyl isobutyl ketone, cyclohexanone or cyclopentanone, an etheric solvent such as diethyl ether or tetrahydrofuran and an esteric solvent such as ethyl acetate, butyl acetate or isobutyl acetate.

The polyamide-imide resin of the present invention is mixed with an epoxy resin as a thermosetting ingredient in a specific rate. As a result thereof, the resulting composition can be used as an adhesive composition for a flexible printed wiring board. Examples of a site in the flexible printed wiring board wherein an adhesive made from the adhesive composition is used are a coverlay film, an adhesive film and a three-layered copper-lined laminated plate.

A coverlay film is composed of (an insulating plastic film)/(an adhesive layer) or (an insulating plastic film)/(an adhesive layer)/(a protective film). The insulating plastic film is a film in 1 to 100 μm thickness made from plastics such as polyimide, polyamide-imide, polyester, polyphenylene sulfide, polyether sulfone, polyether-ether ketone, aramid, polycarbonate or polyarylate. Two or more films selected therefrom may be layered as well. As to the protective film, there is no particular limitation as far as it can be detached without deteriorating characteristic property of the adhesive. Examples thereof include a plastic film such as polyethylene, polypropylene, polyolefin, polyester, polymethylpentene, polyvinyl chloride, polyvinylidene fluoride and polyphenylene sulfide and a film prepared by subjecting the above film to a coating treatment with silicone, fluoride or other releasing agent as well as paper on which the above film is laminated, paper in which the resin having releasing property is impregnated or on which the resin having releasing property is coated, etc.

An adhesive film has such a structure that a protective film is arranged at least on one side of an adhesive layer made from the adhesive composition and has a constitution of (a protective film)/(an adhesive layer) or (a protective film)/(an adhesive)/(a protective film). There may be also such a case wherein an insulating plastic film layer is arranged in an adhesive layer. The adhesive film may be used in a multi-layered printing substrate.

The three-layered copper-lined layered plate has such a structure that a copper foil is adhered at least on one side of an insulating plastic film using an adhesive made from the adhesive composition. Although the copper foil is not particularly limited, a rolled copper foil or an electrolyzed copper foil which has been conventionally used in a flexible printed wiring board may be used therefor.

In any of the above-mentioned uses, a solution of the adhesive composition is applied onto a film or a copper foil to be used as a substrate and then the solvent is dried so as to carry out a thermal compression treatment and a thermal curing treatment followed by subjecting to actual use. In some cases, it is also possible to carry out a heating treatment after drying the solvent whereby the polyamide-imide resin and the epoxy resin are partially made to react for a purpose of adjusting fluidity of the adhesive upon the thermal compression treatment. Incidentally, the state before the thermal compression treatment is called “B stage”.

In any of the above-mentioned applications, heat resistance, adhesive property, flexibility and insulation are demanded after the thermal curing. In addition, it is preferred to exhibit flame retarding property. In the coverlay film and adhesive film, it is general to carry out the process of winding, storing, cutting and punching in a state of B stage. Accordingly, flexibility in a state of B stage is also necessary. On the other hand, in the three-layered copper-lined laminated plate, it is general to carry out the thermal compression treatment and the thermal curing treatment immediately after the formation of the state of B stage. Accordingly, with regard to flexibility in the state of B stage, there is no such a strict demand as being demanded for the coverlay film and adhesive film.

In the adhesive composition of the present invention, the mixing rate of the epoxy resin to 85 to 60 parts by mass of the polyamide-imide resin is preferred to be 15 to 40 parts by mass, and the mixing rate of the epoxy resin to 80 to 65 parts by mass of the polyamide-imide resin is more preferred to be 20 to 35 parts by mass. When the mixing rate of the epoxy resin is too small, it is not possible to form a sufficient cross-linking structure by the reaction with the polyamide-imide resin and heat resistance and insulation after curing of the adhesive are not satisfactory while, when the epoxy resin is too much, the rate of the polyamide-imide resin having excellent heat resistance lowers and the unreacted epoxy resin remains whereby heat resistance after curing of the adhesive lowers.

The epoxy resin used in the adhesive composition of the present invention may be modified with silicone, urethane, polyimide, polyamide, etc. and may also contain sulfur atom, nitrogen atom, etc. in its molecular skeleton. Examples thereof include epoxy resin of a bisphenol A type, epoxy resin of a bisphenol F type, epoxy resin of a bisphenol S type or a hydrogenated product thereof; epoxy resin of a glycidyl ether type such as epoxy resin of a phenol novolak type or epoxy resin of a cresol novolak type; epoxy resin of a glycidyl ester type such as glycidyl hexahydrophthalate or glycidyl ester of dimer acid; and linear aliphatic epoxy resin such as epoxylated polybutadiene or epoxylated soybean oil. Examples of the commercially available products thereof include epoxy resins of a bisphenol A type such as those in the trade names of jER 828 and 1001 manufactured by Mitsubishi Chemicals; epoxy resins of a hydrogenated bisphenol A type such as those in the trade names of ST-2004 and 2007 manufactured by Nippon Steel and Sumikin Chemical; epoxy resins of a bisphenol F type such as those in the trade names of EXA-9726 manufactured by DIC and YDF-170, 2004, etc. manufactured by Nippon Steel and Sumikin Chemical; epoxy resins of a phenol novolak type such as those in the trade names of jER 152 and 154 manufactured by Mitsubishi Chemical, DEN-438 manufactured by Dow Chemical and HP 7200, HP 7200H, etc. manufactured by DIC; epoxy resins of a cresol novolak type such as those in the trade names of YDCN-700 series manufactured by Nippon Steel and Sumikin Kagaku and EOCN-125S, 1035, 1045, etc. manufactured by Nippon Kayaku; flexible epoxy resins such as those in the trade names of YD-171, etc. manufactured by Nippon Steel and Sumikin Chemicals; polyfunctional epoxy resins such as those in the trade names of Epon 10315 manufactured by Mitsubishi Chemical, Araldite 0163 manufactured by Ciba Specialty Chemicals and Denacol EX-611, EX-614, EX-622, EX-512, EX-521, EX-421, EX-411, EX-321, etc. manufactured by Nagase Chemtech; epoxy resins containing heteroring such as those in the trade names of Epikote 604 manufactured Mitsubishi Chemical, YH-434 manufactured by Toto Kasei and Araldite PT 810 manufactured by Ciba Specialty Chemicals; alicyclic epoxy resins such as those in the trade names of Celloxide 2021 and EHPE 3150 manufactured by Daicel Chemical Industry and ERL 4234 manufactured by UCC; epoxy resins of a bisphenol S type such as those in the trade names of Epiclon EXA-1514 manufactured by DIC, etc.; triglycidyl isocyanurate such as those in the trade names of TEPIC manufactured by Nissan Chemical, etc.; epoxy resins of a bixylenol type such as those in the trade names of YX-4000 manufactured by Mitsubishi Chemical, etc.; and epoxy resins of a bisphenol type such as those in the trade names of YL-6056 manufactured by Mitsubishi Chemical, etc. Each of them may be used solely or two or more thereof may be used jointly.

As to the epoxy resin used in the adhesive composition of the present invention, no phosphorus-containing epoxy resin is used or, even if used, a compounding amount of the phosphorus-containing epoxy resin to 100 parts by mass of the polyamide-imide resin is less than 1 part by mass. When the compounding amount of the phosphorus-containing epoxy resin is more than the above rate, flexibility of a coat of the adhesive composition in a state of B stage is deteriorated whereby that is not preferred. The phosphorus-containing epoxy resin is an epoxy resin into which phosphorus atom is incorporated by means of chemical bond using a reactive phosphorus compound and which has one or more epoxy group(s) in a molecule.

In the application such as a three-layered copper-lined laminated plate wherein flexibility of a coat of the adhesive composition in the state of B stage is not so much demanded while high frame retarding property is still demanded, a phosphorus-type flame retardant may be compounded therewith.

Preferred content of phosphorus in a nonvolatile ingredient in the adhesive composition of the present invention is 1.0 to 5.0% by mass, and preferably 1.0 to 3.0% by mass. When the content of phosphorus is too small, no good flame retarding property is achieved while, when it is too much, there is such a tendency that heat resistance, adhesive property and insulating property lower.

As to the phosphorus-type flame retardant used in the present invention, although there is no particular limitation therefor as far as it contains phosphorus in its structure, it is preferred to use phosphazene and phosphinic acid derivatives in view of resistance to hydrolysis, heat resistance and resistance to bleeding out. Each of them may be used solely or two or more thereof may be used jointly.

The phosphazene compound is represented by the following formula (1) or (2). (In the formulae, plural X's are same or different and each is hydrogen, hydroxyl group, amino group, alkyl group, aryl group or organic group; examples of the organic group are alcohol group, phenoxy group, allyl group, cyanophenoxy group and hydroxyphenoxy group; and n is an integer of 3 to 25.)

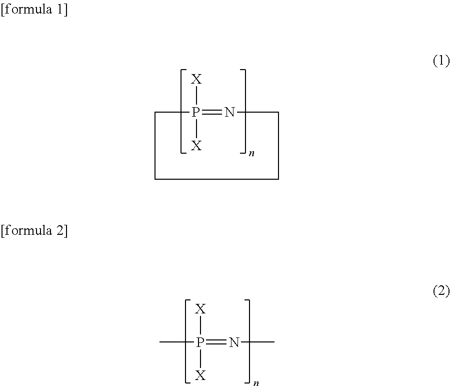

Examples of the commercially available phosphazene as mentioned above are cyclic phenoxy phosphazene (trade names: SPB-100 and SPE-100 manufactured by Otsuka Chemical), cyclic cyanophenoxy phosphazene (trade name: FP-300 manufactured by Fushimi Seiyakusho) and cyclic hydroxyphenoxy phosphazene (trade name: SPH-100 manufactured by Otsuka Chemical). They contain the compound wherein n=3 as a main ingredient and have three functional groups which are reactive with an epoxy group. Phosphazene having no functional group which is reactive with an epoxy resin may result in bleeding out with elapse of time and elute free phosphorus being affected by hydrolysis or the like under severe using conditions whereby electric insulation may lower. Accordingly, it is preferred to choose phosphazene of a reactive type having functional groups which are reactive with the epoxy resin. Specific examples thereof include cyclic hydroxyphenoxy phosphazene having phenolic hydroxyl groups.

As to the phosphinic acid derivative, a phosphinic acid derivative of a phenanthrene type is preferred. Examples thereof include 9,10-dihydro-9-oxa-10-phosphaphenanthrene-10-oxide (trade name: HCA manufactured by Sanko), 10-benzyl-10-hydro-9-oxa-10-phosphaphenanthrene-10-oxide (trade name: BCA manufactured by Sanko) and 10-(2,5-dihydroxyphenyl)-10-H-9-oxa-10-phosphaphenanthrene-10-oxide (trade name: HCA-HQ manufactured by Sanko). Among the above-mentioned phosphinic acid derivatives, although HCA is reactive to the epoxy resin, it result in the bleeding out and is sometimes inferior in the resistance to high temperature and to high humidity whereby its compounding amount is to be appropriately selected taking the properties into consideration. Besides the above-mentioned phosphorus compounds, other phosphorus compound(s) may be used either solely or jointly by combining two or more upon necessity within such an extent that flame retarding property, heat resistance to solder and resistance to bleeding out are not deteriorated.

As to the phosphorus-type flame retardant, it is preferred that (i) a phosphorus-type flame retardant having no functional group which is reactive with epoxy and (ii) a phosphorus-type flame retardant having two or more or, particularly, three functional groups which are reactive with epoxy are used together. The rate of the phosphorus-type flame retardant of (i):(ii) is preferred to be from 1:9 to 9:1, and more preferred to be from 2:8 to 8:2, in terms of the ratio by mass. When the amount of the phosphorus-type flame retardant of (i) is too much, resistance to moist heat is inferior while, when the amount of the phosphorus-type flame retardant of (ii) is too much, there is a possibility that the adhesive property is inferior.

Since the phosphorus-type flame retardant (i) having no functional group which is reactive with epoxy is not incorporated into the cross-linking structure upon thermal curing, it plays a role of imparting flexibility to the adhesive composition after the thermal curing. For example, the above-mentioned cyclic phenoxyphosphazene (trade names: SPB-100 and SPE-100 manufactured by Otsuka Chemical), cyclic cyanophenoxy phosphazene (trade name: FP-300 manufactured by Fushimi Seiyakusho), 10-benzyl-10-hydro-9-oxa-10-phosphaphenanthrene-10-oxide (trade name: BCA manufactured by Sanko), a phosphate type (trade name: PX-200 manufactured by Daihachi Kagaku), etc. correspond thereto. The phosphorus-type flame retardant (ii) having two or more functional groups which are reactive with epoxy is incorporated into the cross-linking structure upon the thermal curing. As a result, it has a role of suppressing the bleeding out and of preventing decrease of the heat resistance. For example, the above-mentioned cyclic hydroxyphenoxy phosphazene (trade name: SPH-100 manufactured by Otsuka Chemical), 10-(2,5-dihydroxyphenyl)-10-H-9-oxa-10-phosphaphenanthrene-10-oxide (trade name: HCA-HQ manufactured by Sanko), etc. correspond thereto. Here, in the case of a substance having one functional group which is reactive with epoxy, it becomes a terminal of the cross-linking structure and breaks the network whereby there is a possibility that the effect of prevention of decrease of the heat resistance of (ii) is not well achieved.

Generally, the epoxy resin contains chlorine as an impurity during the course of its production. However, there has been a demand to lower an amount of halogen in view of reduction of environmental load and it has been also known that, when chlorine or, particularly, hydrolyzable chlorine is abundant, insulating property lowers. Accordingly, a total amount of chlorine in the nonvolatile ingredient of the adhesive composition is preferred to be 500 ppm or less.

In the coverlay film of the present invention, an amount of residual solvent in the coverlay film in a state of B stage is preferred to be less than 1.5% by mass. Further, in the adhesive film of the present invention, an amount of residual solvent in the adhesive film in a state of B stage is preferred to be less than 1.5% by mass. The residual solvent is a solvent which was used in the adhesive composition and which could not be removed in the step for making into a B stage. When two or more solvents are combined and used, a solvent of higher boiling point resides. For example, the main ingredient in Examples of the present invention is dimethylacetamide. Since insulating property lowers when the residual solvent amount is abundant, the amount of residual solvent in the state of B stage is preferred to be less than 1.5% by mass as mentioned above.

To the adhesive composition of the present invention, a highly heat-resisting resin may be added within such an extent that the effect of the present invention is not deteriorated thereby, for enhancing reliability of insulation under high temperature and high humidity in a high level. As to the highly heat-resisting resin, it is preferred to be a resin having glass transition temperature of 200° C. or higher or, more preferably, 250° C. or higher. Although there is no particular limitation therefor, specific examples thereof include a polyimide resin, a polyamide-imide resin, a polyether imide resin and a polyether ether ketone resin. In addition, the highly heat-resisting resin is preferred to be soluble in a solvent. As to a resin which satisfies those conditions, resins wherein an amount of an anhydride of polycarboxylic acid having an aromatic ring is 90 mol % or more when an amount of the constituent unit derived from the total acid ingredients is taken as 100 mol % are preferred and, among them, a polyamide-imide resin is most preferred. Specific materials have been mentioned already. As to a compounding amount of the highly heat-resisting resin as such, it is preferred to be 10 to 80 parts by mass, and more preferred to be 20 to 60 parts by mass, to 100 parts by mass of the polyamide-imide resin satisfying the above (a) to (c). When the compounding amount is too small, curing is hardly achieved while, when it is too much, a coat in a B stage becomes hard and lamination is hardly resulted whereby adhesive strength may be hardly expressed.

To the adhesive composition of the present invention, glycidylamine may be added thereto in addition the above epoxy resin for a purpose of suppressing fluidity of the adhesive composition upon lamination within such an extent that the effect of the present invention is not deteriorated thereby. An amount of the glycidylamine to be added is preferred to be 0.01 to 5% by mass, and more preferred to be 0.05 to 2% by mass, to the total weight of polyamide-imide resin and epoxy resin in the adhesive composition. When the adding amount of the glycidylamine is too much, fluidity of the adhesive composition upon lamination becomes too small whereby there is a possibility that embedding property of the circuit lowers while, when the adding amount is too small, there is a possibility that the effect of suppressing fluidity cannot be sufficiently achieved. Examples of the glycidylamine include TETRAD-X and TETRAD-C (trade names) manufactured by Mitsubishi Gas Chemical, GAN (trade name) manufacture by Nippon Kayaku and ELM-120 (trade name) manufactured by Sumitomo Chemical. Each of them may be used solely or two or more thereof may be used jointly.

To the adhesive composition of the present invention, a curing agent or a curing promoter for the epoxy resin may be added within such an extent that the characteristic property is not deteriorated thereby. As to the curing agent, although there is no particular limitation as far as it is a compound being reactive with the epoxy resin, examples thereof include a curing agent of an amine type, a compound having a phenolic hydroxyl group, a compound having carboxylic acid and a compound having acid anhydride. As to the curing promoter, although there is no particular limitation as far as it promotes the reaction of the epoxy resin with the polyamide-imide resin and the above curing agent, examples thereof include imidazole derivatives such as 2MZ, 2E4MZ, C₁₁Z, C₁₇Z, 2PZ, 1B2MZ, 2MZ-CN, 2E4MZ-CN, C₁₁Z-CN, 2PZ-CN, 2PHZ-CN, 2MZ-CNS, 2E4MZ-CNS, 2PZ-CNS, 2MZ-AZINE, 2E4MZ-AZINE, C₁₁Z-AZINE, 2MA-OK, 2P4MHZ, 2PHZ and 2P4BHZ manufactured by Shikoku Kasei Kogyo; guanamines such as acetguanaraine and benzoguanamine; polyamines such as diaminodiphenylmethane, m-phenylenediamine, m-xylylene-diamine, diaminodiphenylsulfone, dicyandiamide, urea, urea derivatives, melamine and polybasic hydrazide; an organic acid salts and/or an epoxy adducts thereof; an amine complex of boron trifluoride; triazine derivatives such as ethyldiamino-S-triazine, 2,4-diamino-S-triazine and 2,4-diamino-6-xylyl-S-triazine; tertiary amines such as trimethylamine, triethanolamine, N,N-dimethyloctylamine, N-benzyldimethylamine, pyridine, N-methylmorpholine, hexa(N-methyl) melamine, 2,4,6-tris(dimethylaminophenol), tetramethylguanidine, DBU (1,8-diazabicyclo[5.4.0]-7-undecene) and DBN (1,5-diazabicyclo[4.3.0]-5-nonene); organic acid salts and/or tetraphenylboroates thereof; polyvinylphenol, polyvinylphenol bromide; organic phosphines such as tributylphosphine, triphenylphosphine and tris-2-cyanoethylphosphine; quaternary phosphonium salts such as tri-n-butyl(2,5-dihydroxyphenyl)phosphonium bromide, hexadecyltributylphosphonium chloride and tetraphenyl-phosphonium tetraphenylboroate; quaternary ammonium salts such as benzyltrimethylammonium chloride and phenyltributyl-ammonium chloride; the above polycarboxylic acid anhydride; catalysts for optical cationic polymerization such as diphenyliodonium tetrafluoroborate, triphenylsulfonium hexafluoroantimonate, 2,4,6-triphenylthiopyrylium hexa-fluorophospohate, Irgacure 261 (manufactured by Ciba Specialty Chemicals) and Optomer SP-170 (manufactured by Adeka); a styrene-maleic acid anhydride resin; an equimolar reaction product of phenyl isocyanate, with dimethylamine; and equimolar reaction products of organic polyisocyanate (such as tolylene diisocyanate or isophorone diisocyanate) with dimethylamine. Each of those curing agents and curing promoters may be used solely or two or more thereof may be used jointly.

A silane coupling agent may be added to the adhesive composition of the present invention for a purpose of enhancing adhesive property. There is no particular limitation therefor as far as it is a conventionally known silane coupling agent. Specific examples thereof include aminosilanes, mercaptosilane, vinylsilane, epoxysilane, methacrylsilane, isocyanatesilane, ketiminesilane, a mixture or a reaction product thereof and compounds prepared from the above with polyisocyanate. Examples of the silane coupling agent as such include aminosilanes such as 3-aminopropyltrimethoxysilane, 3-aminopropyltriethoxysilane, 3-aminopropylmethyldimethoxysilane, 3-aminopropylethyldiethoxysilane, bistrimethoxysilylpropylamine, bistriethoxysilylpropylamine, bismethoxydimethoxysilylpropylamine, bisethoxydiethoxysilylpropylamine, N-2-(aminoethyl)-3-aminopropyltrimethoxysilane, N-2-(aminoethyl)-3-aminopropylmethyldimethoxysilane, N-2-(amino-ethyl)-3-aminopropyltriethoxysilane and N-2-(aminoethyl)-3-aminopropylethyldiethoxysilane; mercaptosilanes such as γ-mercaptopropyltrimethoxysilane, γ-mercaptopropyltriethoxysilane, γ-mercaptopropylmethyldimethoxysilane, γ-mercaptopropylmethyldiethoxysilane and γ-mercaptopropylethyldiethoxysilane; vinylsilanes such as vinyltrimethoxysilane, vinyltriethoxysilane and tris-(2-methoxyethoxy)vinylsilane; epoxysilanes such as γ-glycidoxypropyltrimethoxysilane, γ-glycidoxypropyldimethylethoxysilane, γ-glycidoxypropylmethyldiethoxysilane, β-(3,4-epoxycyclohexyl)ethylmethyldimethoxysilane, γ-glycidoxypropyltrimethoxysilane and β-(3,4-epoxycyclohexyl)ethyltrimethoxysilane; methacrylsilanes such as 3-methacryloxypropylmethyldimethoxysilane, 3-methacryloxypropyltrimethoxysilane, 3-methacryloxypropylmethyldiethoxysilane and 3-methacryl-oxypropyltriethoxysilane; isocyanate silane such as propyltriethoxysilane isocyanate and propoyltrimethoxysilane isocyanate; and ketiminesilanes such as ketiminized propyltrimethoxysilane and ketiminized propyltriethoxysilane. Each of them may be used solely or two or more thereof may be used jointly. Since epoxysilanes among those silane coupling agents have a reactive epoxy group, they can react with a polyamide-imide resin whereby they are preferred in view of enhancement of heat resistance and moist heat resistance. A compounding amount of the silane coupling agent when the total amount of nonvolatile ingredient in the adhesive composition is taken as 100% by mass is preferably 0 to 3% by mass and, more preferably, 0 to 2% by mass. When the compounding amount is out of the above range, there is a tendency that the heat resistance lowers.

To the adhesive composition of the present invention, organic/inorganic filler may be added for a purpose of enhancement of resistance to solder heat within such an extent that the effect of the present invention is not deteriorated thereby. As to the organic filler, there may be exemplified powder of polyimide or polyamide-imide which is a heat resisting resin. As to the inorganic filler, there may be exemplified silica (SiO₂), alumina (Al₂O₃), titania (TiO₂), tantalum oxide (Ta₂O₅), zirconia (ZrO₂), silicon nitride (Si₃N₄), barium titanate (BaO.TiO₂), barium carbonate (BaCO₃), lead titanate (PbO.TiO₂), lead titanate zirconate (PZT), lanthanum lead titanate zirconate (PLZT), gallium oxide (Ga₂O₃), spinel (MgO.Al₂O₃), mullite (3Al₂O₃.2SiO₂), cordierite (2MgO.2Al₂O₃. 5SiO₂), talc (3MgO.4SiO₂—H₂O), aluminum titanate (TiO₂—Al₂O₃), yttria-containing zirconia (Y₂O₃—ZrO₂), barium silicate (BaO. 8SiO₂), boron nitride (BN), calcium carbonate (CaCO₃), calcium sulfate (CaSO₄), zinc oxide (ZnO), magnesiumtitanate (MgO. TiO₂), barium sulfate (BaSO₄), organic bentonite, clay, mica, aluminum hydroxide and magnesium hydroxide. Among them, silica is preferred in view of its easy dispersing property and of the effect for enhancing heat resistance. Each of them may be used solely or two or more thereof may be used jointly. An adding amount of the organic/inorganic filler as such to the nonvolatile ingredient of the adhesive composition is preferred to be 1 to 30% by mass, and more preferred to be 3 to 15% by mass. When adding amount of the organic/inorganic filler is too much, coat of the adhesive became brittle while, when it is too small, there is a possibility that the effect for enhancing heat resistance cannot be sufficiently achieved.

The adhesive composition containing the polyamide-imide resin and the epoxy resin according to the present invention is excellent in adhesive property and can strongly adhere the polyimide film to the copper foil. The resulting layered product of copper polyimide film is excellent in heat resistance and insulating property. The reason therefor is likely to be as follows: In a polyamide-imide resin wherein acrylonitrile-butadiene rubber and aliphatic dicarboxylic acid having a carbon number of 4 to 12 are copolymerized in a specific range, introduction of an aliphatic group enhances the solubility in a solvent. At the same time, chain length of the aliphatic group is neither too short nor too long and the aliphatic group is appropriately distributed in the polyamide-imide resin. Accordingly, as a result of adhesive property of the acrylonitrile-butadiene rubber, flexibility of the aliphatic dicarboxylic acid, and high polarity of the introduced amide group, adhesive property is now synergically enhanced. In addition, it also participates in the above characteristic that crosslink could be appropriately formed by means of the thermal curing due to the fact that the rate of the polyamide-imide resin to the epoxy resin is within a specific range.

### EXAMPLES

As hereunder, effects of the present invention will be demonstrated by way of Examples although the present invention is not limited to those Examples only. Evaluations of the characteristics in Examples were carried out according to the following methods.

Adhesive Property

A solution of the adhesive composition was applied to a polyimide film (Apical 12.5 NPI manufactured by Kaneka) so as to make the thickness thereof after drying 20 μm and then dried at 140° C. for 3 minutes using a hot-air drier to give a sample in the state of B stage. Aside of this B stage sample to which the adhesive agent was applied and a glossy side of a copper foil (BHY manufactured by JX Nikko Nisseki; thickness: 18 RI) were subjected to a thermal compression treatment using a vacuum press laminating machine in vacuo at 160° C. and 3 MPa for 30 seconds. After that, a thermal curing treatment was carried out at 150° C. for 4 hours. From the sample after the curing, the polyimide film was peeled off using a tensile tester (Autograph AG-X plus manufactured by Shimadzu) under an environment of 25° C. in a direction of 90° at a rate of 50 mm/minute whereupon adhesive strength was measured.

When the sample exhibited adhesive strength of 0.5 N/mm or more, it was evaluated as ◯. When the sample exhibited adhesive strength of less than 0.5 N/mm, it was evaluated as x.

Flame Retarding Property

A sample in B stage was prepared in the same manner as in the case for the evaluation of adhesive property. Then, a side to which the adhesive was applied and a polyimide film (Apical 12.5 NPI manufactured by Kaneka) were subjected to a thermal compression treatment using a vacuum press laminating machine in vacuo at 160° C. and 3 MPa for 30 seconds. After that, a thermal curing treatment was carried out at 150° C. for 4 hours. The sample after the curing was subjected to evaluation for flame retarding property in accordance with UL-94VTM standard.

When the sample satisfied VTM-0, it was evaluated as ◯. When the sample did not satisfy VTM-0, was evaluated as x.

Embrittlement in B Stage

A solution of the adhesive composition was applied to a PET film (E 5101 manufactured by Toyobo; thickness: 50 μm) so as to make the thickness thereof after drying 20 μm and then dried at 140° C. for 3 minutes to give a sample in a state of B stage.

The sample was bent and when the adhesive layer was cracked immediately after application/drying of the adhesive, it was evaluated as x. When the adhesive layer was cracked after one week at room temperature, it was evaluated as A. When the adhesive layer was not cracked even after one week at room temperature, it was evaluated as ◯.

Reliability for Insulating Property

A sample in B stage was prepared in the same manner as in the case for the evaluation of adhesive property. Then, it was subjected to a thermal compression treatment using a vacuum press laminating machine at 160° C. and 3 MPa for 30 seconds in vacuo, in a comb pattern with L/S=50/50 μm. After that, a thermal curing treatment was carried out at 150° C. for 4 hours. Voltage of 200 V was applied thereto for 250 hours under the environment wherein the temperature was 85° C. and the humidity was 85%.

When the resistance after 250 hours was 1×10⁹Ω or more and no dendrite was found, it was evaluated as oo. When the resistance after 250 hours was 1×10⁸Ω or more and less than 1×10⁹Ω or more and no dendrite was found, it was evaluated as ◯. When the resistance after 250 hours was less than 1×10⁸Ω or dendrite was generated, it was evaluated as x.

Heat Resistance to Solder

A sample was prepared in the same manner as in the case for the evaluation of adhesive property. Then, it was cut into 20-mm squares and floated on a solder bath of 300° C. in such a state that the polyimide surface was made upside.

When neither swelling nor detachment was found, it was marked as ◯. When either swelling or detachment was found, it was marked as x.

Polymerization of Polyamide-Imide Resins 1 to 9

Polymerization of the polyamide-imide resin was carried out using the starting material resin composition (mol %) as shown in Table 1. To be more specific, polymerization was carried out as follows in the case of the polyamide-imide resin 1.

Trimellitic anhydride (105.67 g, 0.55 mol), 80.90 g (0.40 mol) of sebacic acid, 175 g (0.05 mol) of acrylonitrile butadiene rubber having carboxyl groups in both terminals, 250.25 g (1.00 mol) of 4,4′-diphenylmethane diisocyanate and 785.7 g of dimethylacetamide were added to a four-necked separable flask equipped with a stirrer, a cooling pipe, a nitrogen-introducing pipe and a thermometer so as to make the concentration of the resin after decarbonization 40% by weight. Then, the mixture was made to react for 2 hours by raising the temperature up to 100° C. under nitrogen atmosphere and further heated up to 150° C. and the reaction was carried out for 5 hours. After that, 436.5 g of dimethylacetamide was added thereto for dilution so as to make the concentration of the resin 30% by weight whereupon a solution of the polyamide-imide resin 1 was prepared. With regard to other polyamide-imide resins 2 to 9, polymerization of the resin was carried out using the starting material resin compositions as shown in Table 1 to give the solutions.

Polymerization of highly heat-resisting resin (polyamide-imide resin 10)

As a highly heat-resisting resin, the polyamide-imide resin 10 solely consisting of a material having an aromatic ring (trimellitic anhydride) was polymerized in the same manner as in the above case for the polyamide-imide resin 1. A solution of the resulting polyamide-imide resin 10 was applied onto a copper foil so as to make the thickness thereof after drying 15 μm, dried at 100° C. for 5 minutes and further subjected to drying using hot air at 250° C. for 1 hour. After that, the sample was dipped into a solution of ferric chloride to remove the copper foil whereupon a film of the polyamide-imide 10 was prepared. Dynamic viscoelasticity of the product was measured using DVA-220 (a dynamic viscoelasticity measuring device manufactured by IT Keisoku Seigyosha) under the frequency of 110 Hz and the temperature-rising rate of 4° C./minute. The glass transition temperature of the resulting polyamide-imide 10 was calculated from the inflection point of the storage elastic modulus thereof and found to be 280° C.

Preparation of Solutions of Adhesive Compositions

Solutions of the adhesive compositions of Examples 1 to and Comparative Examples 1 to 7 dissolved in dimethylacetamide were prepared according to the adhesive compounding rate (in % by mass of solid) as shown in Table 2 and the above properties were evaluated.

TABLE 1

| | | | | | | | | | | | highly |
|---|---|---|---|---|---|---|---|---|---|---|---|
| | | poly- | poly- | poly- | poly- | poly- | poly- | poly- | poly- | poly- | heat-resisting |
| | | amide- | amide- | amide- | amide- | amide- | amide- | amide- | amide- | amide- | resin |
| | | imide | imide | imide | imide | imide | imide | imide | imide | imide | (polyamide-imide |
| | material | resin 1 | resin 2 | resin 3 | resin 4 | resin 5 | resin 6 | resin 7 | resin 8 | resin 9 | resin 10) |
| resin | NBR | 2.5 | 1.5 | 2 | 2.5 | 5 | 2.5 | 2.5 | 0.5 | 10 | — |
| composition | sebacic acid | 40 | 40 | 35 | 50 | 40 | — | 40 | 40 | 40 | — |
| (mol %) | decanoic diacid | — | — | — | — | — | 40 | — | — | — | — |
| | TMA | 57.5 | 58.5 | 63 | 47.5 | 55 | 57.5 | — | 59.5 | 50 | 100 |
| | H-TMA | — | — | — | — | — | — | 57.5 | — | — | — |
| | MDI | 100 | 100 | 100 | 100 | 100 | 100 | 100 | 100 | 100 | 100 |

NBR: modified acrylonitrile-butadiene rubber having carboxyl groups in both terminals
TMA: trimellitic anhydride
H-TMA: cyclohexane-1,2,4-tricarboxylic acid-1,2-anhydride
MDI: diphenylmethane-4,4′-diisocyanate

TABLE 2

| | | | Exam- | Exam- | Exam- | Exam- | Exam- | Exam- | Exam- | Exam- | Exam- | Exam- | Exam- |
|---|---|---|---|---|---|---|---|---|---|---|---|---|---|
| | | | ple 1 | ple 2 | ple 3 | ple 4 | ple 5 | ple 6 | ple 7 | ple 8 | ple 9 | ple 10 | ple 11 |
| adhesive | polyamide-imide resin 1 | | 60 | — | — | — | — | — | 50 | 60 | 60 | 65 | 40 |
| compounding rate | polyamide-imide resin 2 | | — | 60 | — | — | — | — | — | — | — | — | — |
| [in % by mass | polyamide-imide resin 3 | | — | — | 60 | — | — | — | — | — | — | — | — |
| of solid] | polyamide-imide resin 4 | | — | — | — | 60 | — | — | — | — | — | — | — |
| | polyamide-imide resin 5 | | — | — | — | — | 60 | — | — | — | — | — | — |
| | polyamide-imide resin 6 | | — | — | — | — | — | 60 | — | — | — | — | — |
| | polyamide-imide resin 7 | | — | — | — | — | — | — | — | — | — | — | — |
| | polyamide-imide resin 8 | | — | — | — | — | — | — | — | — | — | — | — |
| | polyamide-imide resin 9 | | — | — | — | — | — | — | — | — | — | — | — |
| | polyamide-imide resin 10 | | — | — | — | — | — | — | — | — | — | — | 20 |
| | epoxy resin | jER 152 | 16 | 16 | 16 | 16 | 16 | 16 | 26 | 16 | 16 | 23 | 16 |
| | | EXA-9726 | — | — | — | — | — | — | — | — | — | — | — |
| | phosphorus- | BCA | 18 | 18 | 18 | 18 | 18 | 18 | 18 | 12 | 6 | 7 | 18 |
| | type flame | HCA | — | — | — | — | — | — | — | — | — | — | — |
| | retardant | SPH-100 | 6 | 6 | 6 | 6 | 6 | 6 | 6 | 12 | 18 | 5 | 6 |

| | | | | | | | | | | | | |
|---|---|---|---|---|---|---|---|---|---|---|---|---|
| | content of phosphorus | 2.6 | 2.6 | 2.6 | 2.6 | 2.6 | 2.6 | 2.6 | 2.7 | 2.9 | 1.3 | 2.6 |
| adhesive | adhesive property | ∘ | ∘ | ∘ | ∘ | ∘ | ∘ | ∘ | ∘ | ∘ | ∘ | ∘ |
| characteristics | flame retarding property | ∘ | ∘ | ∘ | ∘ | ∘ | ∘ | ∘ | ∘ | ∘ | ∘ | ∘ |
| | embrittlement in B stage | ∘ | ∘ | ∘ | ∘ | ∘ | ∘ | ∘ | ∘ | ∘ | ∘ | ∘ |
| | reliability for the | ∘ | ∘ | ∘ | ∘ | ∘ | ∘ | ∘ | ∘ | ∘ | ∘ | ∘ ∘ |
| | insulating property | | | | | | | | | | | |
| | heat resistance to solder | ∘ | ∘ | ∘ | ∘ | ∘ | ∘ | ∘ | ∘ | ∘ | ∘ | ∘ |

| | | | Comparative | Comparative | Comparative | Comparative | Comparative | Comparative | Comparative |
|---|---|---|---|---|---|---|---|---|---|
| | | | Example 1 | Example 2 | Example 3 | Example 4 | Example 5 | Example 6 | Example 7 |
| adhesive | polyamide-imide resin 1 | | — | — | — | 70 | 40 | 60 | 60 |
| compounding rate | polyamide-imide resin 2 | | — | — | — | — | — | — | — |
| [in % by mass | polyamide-imide resin 3 | | — | — | — | — | — | — | — |
| of solid] | polyamide-imide resin 4 | | — | — | — | — | — | — | — |
| | polyamide-imide resin 5 | | — | — | — | — | — | — | — |
| | polyamide-imide resin 6 | | — | — | — | — | — | — | — |
| | polyamide-imide resin 7 | | 60 | — | — | — | — | — | — |
| | polyamide-imide resin 8 | | — | 60 | — | — | — | — | — |
| | polyamide-imide resin 9 | | — | — | 60 | — | — | — | — |
| | polyamide-imide resin 10 | | — | — | — | — | — | — | — |
| | epoxy resin | jER 152 | 16 | 16 | 16 | 6 | 36 | — | 10 |
| | | EXA-9726 | — | — | — | — | — | 16 | 6 |
| | phosphorus- | BCA | 18 | 18 | 18 | 18 | 18 | 18 | 18 |
| | type flame | HCA | — | — | — | — | — | — | — |
| | retardant | SPH-100 | 6 | 6 | 6 | 6 | 6 | 6 | 6 |

| | | | | | | | | |
|---|---|---|---|---|---|---|---|---|
| | content of phosphorus | 2.6 | 2.6 | 2.6 | 2.6 | 2.6 | 3.0 | 2.7 |
| adhesive | adhesive property | ∘ | x | ∘ | ∘ | ∘ | ∘ | ∘ |
| characteristics | flame retarding property | ∘ | ∘ | ∘ | ∘ | ∘ | ∘ | ∘ |
| | embrittlement in B stage | ∘ | x | ∘ | ∘ | ∘ | Δ | Δ |
| | reliability for the | ∘ | ∘ | x | x | x | ∘ | ∘ |
| | insulation property | | | | | | | |
| | heat resistance to solder | x | ∘ | ∘ | ∘ | x | ∘ | ∘ |

jER 152: manufactured by Mitsubishi Chemical; epoxy resin (containing no phosphorus)
EXA-9726: manufactured by DIC; phosphorus-containing epoxy resin
BCA: manufactured by Sanko; phosphorus-type flame retardant having no functional group which is reactive with epoxy
HCA: manufactured by Sanko; phosphorus-type flame retardant having one functional group which is reactive with epoxy
SPH-100: manufactured by Otsuka Chemical; phosphorus-type flame retardant having three functional groups which are reactive with epoxy

As will be noted from Table 2, the adhesive compositions of Examples 1 to 11 satisfying the conditions of the present invention showed excellent results in terms of adhesive property, flame retarding property, embrittlement in B stage, reliability for insulating property and heat resistance to solder. On the contrary, in Comparative Examples 1 to 3 using polyamide-imide resins which do not satisfy the conditions of the present invention, in Comparative Examples 4 and 5 wherein the compounding rate of polyamide-imide resin to epoxy resin is out of the scope of the present invention and in Comparative Examples 6 and 7 using more than the predetermined amount of phosphorus-containing epoxy resin, the result for any of the properties was not satisfactory.

### INDUSTRIAL APPLICABILITY

The adhesive composition of the present invention is excellent in terms of insulating property, flexibility, flame retarding property and fluidity. Accordingly, the adhesive composition of the present invention is suitable for a coverlay film, an adhesive film, a three-layered copper-line laminated plate, etc. whereby it is quite useful.

1. An adhesive composition wherein a polyamide-imide resin and an epoxy resin are compounded, characterized in that said adhesive composition has characteristics of the following (A) to (C):
(A) 15 parts by mass to 40 parts by mass of the epoxy resin is compounded to 85 parts by mass to 60 parts by mass of the polyamide-imide resin;
(B) No phosphorus-containing epoxy resin is used as the epoxy resin or, even if used, a compounding amount of the phosphorus-containing epoxy resin to 100 parts by mass of the polyamide-imide resin is less than 1 part by mass; and
(C) The polyamide-imide resin is a polyamide-imide resin comprising a constituent unit derived from acid ingredients of the following (a) to (c) and a constituent unit derived from a diisocyanate ingredient having an aromatic ring or derived from a diamine ingredient having an aromatic ring and,
when the constituent units derived from total acid ingredients in the polyamide-imide resin are taken as 100 mol %, a rate of each constituent unit derived from each acid ingredient is 1 to 6 mol % for (a), 10 to 80 mol % for (b) and 10 to 89 mol % for (c):
(a) acrylonitrile-butadiene rubber which has carboxyl groups in both terminals, has weight-average molecular weight of 500 to 5,000, and has a rate of an acrylonitrile moiety of 10 to 50% by mass;
(b) aliphatic dicarboxylic acid which has a carbon number of 4 to 12; and
(c) anhydride of polycarboxylic acid which has an aromatic ring.

2. The adhesive composition according to claim 1, wherein a phosphorus-type flame retardant is further compounded therewith and a content of phosphorus in a nonvolatile ingredient in the adhesive composition is 1.0 to 5.0% by mass.

3. The adhesive composition according to claim 2, wherein a phosphorus-type flame retardant having no functional group which is reactive with epoxy and a phosphorus-type flame retardant having two or more functional groups which are reactive with epoxy are jointly used as the phosphorus-type flame retardant.

4. The adhesive composition according to claim 1, wherein a total amount of chlorine of the epoxy resin is 500 ppm or less in the nonvolatile ingredient of the adhesive composition.

5. The adhesive composition according to claim 1, wherein a resin having glass transition temperature of 200° C. or higher is further compounded therewith.

6. A coverlay film which is comprising an adhesive layer made from the adhesive composition mentioned claim 1.

7. The coverlay film according to claim 6, wherein an amount of residual solvent in the coverlay film in a state of B stage is less than 1.5% by mass.

8. An adhesive film which is comprising an adhesive layer made from the adhesive composition mentioned in claim 1.

9. The adhesive film according to claim 8, wherein an amount of residual solvent in the adhesive film in a state of B stage is less than 1.5% by mass.

10. A three-layered copper-lined layered plate which is comprising an adhesive layer made from the adhesive composition mentioned in claim 1.

11. A flexible printed wiring board which comprises the adhesive composition mentioned in claim 1.

12. A flexible printed wiring board which comprises the coverlay film mentioned in claim 6.

13. A flexible printed wiring board which comprises the adhesive film mentioned in claim 8.

14. A flexible printed wiring board which comprises the three-layered copper-lined layered plate mentioned in claim 10.
